(19) United States
(12) Patent Application Publication
(10) Pub. No.: US 2012/0313108 A1
(43) Pub. Date: Dec. 13, 2012

(54) SEMICONDUCTOR DIODE

(75) Inventors: Tadayoshi TSUCHIYA, Ishioka-shi (JP); Naoki KANEDA, Tsuchiura-shi (JP); Tomoyoshi MISHIMA, Shiki-shi (JP); Toshihiro KAWANO, Ome-shi (JP); Toru NAKAMURA, Mitaka-shi (JP); Kazuki NOMOTO, Koganei-shi (JP)

(73) Assignee: HITACHI CABLE, LTD., Tokyo (JP)

(21) Appl. No.: 13/488,954

(22) Filed: Jun. 5, 2012

(30) Foreign Application Priority Data
Jun. 8, 2011 (JP) JP2011-128535

(51) Int. Cl. H01L 29/20

(52) U.S. Cl. 257/76; 257/E29.089

(57) ABSTRACT

To provide a semiconductor diode with a part of a semiconductor lamination portion having a mesa structure portion, which is the part where a pn-junction is formed by lamination of an n-type semiconductor layer and a p-type semiconductor layer on a substrate, comprising: a protective insulating film formed by coating a main surface of the mesa structure portion, a side face of the mesa structure portion in which an interface of the pn-junction is exposed, and an etched and exposed surface of the n-type semiconductor layer; and an anode electrode formed in ohmic-contact with the p-type semiconductor layer exposed from an opening formed on a part of the main surface of the mesa structure portion of the protective insulating film, extending from the main surface, through the side face of the mesa structure portion, to the surface of the n-type semiconductor layer.

The present application is based on Japanese Patent Application No. 2011-128535 filed on Jun. 8, 2011, the entire contents of which are hereby incorporated by reference.

### TECHNICAL FIELD

The present invention relates to a semiconductor diode having a pn-junction, and particularly relates to the semiconductor diode having a new anode electrode shape.

### DESCRIPTION OF RELATED ART

A pn-junction diode using a nitride semiconductor is paid attention to as a large capacity rectifying device of the next generation, due to its high breakdown voltage and because low-current application loss can be expected.

Conventionally, in an anode electrode of a Schottky Barreir Diode (SBD), a field plate structure is employed for relaxing an electric field concentration to an electrode end (for example, see patent documents 1, 2, 4), wherein a technique used in silicon SBD is applied. The field plate structure is a structure in which a protective insulating film formed on a semiconductor is covered with apart of the anode electrode. Owing to this field plate structure, the electric field concentration to an end portion of a junction surface between the anode electrode and the semiconductor can be relaxed, and a reverse withstand voltage property of the device can be improved.

In the pn-junction diode, it is said that application of the aforementioned field plate structure for the anode electrode which is disposed on a crystal surface is not generally effective, because the electric field is concentrated to an overall pn-junction interface inside of a semiconductor crystal.

However, in a planar structure in which a p-type layer is embedded into an n-type layer, and both the anode electrode and the cathode electrode are formed on the crystal surface, it is effective to use a method for covering the protective insulating film of a portion extending from a surface exposed portion of the pn-junction interface to the surface of the n-type layer, by a part of the anode electrode (for example, see patent document 3). In the planar structure, the most concentrated portion of the electric field in the pn-junction, exists not in an overall junction part, but at a position connecting the anode electrode and the cathode electrode with a shortest distance, namely in the vicinity of the surface. Therefore, the concentration of the electric field to the vicinity of the surface of the pn-junction interface can be relaxed by extending the anode electrode as a field plate, and the reverse withstand voltage property of the device can be improved. Although this is an example in a case of silicon, an underlined physical phenomenon is common to the whole field of the semiconductor, and is a concept that can be applied to a compound semiconductor including a nitride semiconductor.

Further, there is proposed a technique that high withstand voltage of a Schottky barrier junction diode is achieved by electrically connecting an anode electrode in a compound semiconductor region laminated on the electroconductive substrate and an electroconductive substrate (for example, see patent document 5).

### PATENT DOCUMENTS

Patent document 1: Patent Publication No. 3201410
Patent document 2: Patent Publication No. 3875184
   Patent document 3:
Japanese Patent Laid Open Publication No. 1989-136366
   Patent document 4:
Japanese Patent Laid Open Publication No. 2009-194225
   Patent document 5:
Japanese Patent Laid Open Publication No. 2008-124409

### SUMMARY OF THE INVENTION

However, it is conventionally considered that an effect obtained by employing the field plate structure by the aforementioned pn-junction diode is specific to the planar structure in which the electric field is concentrated to the pn-junction portion in the vicinity of the surface, and such an effect is not applied to a simple pn-junction structure in which the cathode electrode is formed on a rear surface side of a substrate, and in order to improve the reverse withstand voltage property, there is no method but reducing a carrier concentration of a p-type layer and an n-type layer, and weakening a field intensity over an entire body of the pn-junction portion. However, a method for reducing a carrier concentration involves a problem of increasing on-resistance of the pn-junction diode, thus increasing the current application loss.

Further, a lattice defect in the crystal is also considered to be one of the causes of deteriorating the reverse withstand voltage property. Also, it is considered that inherent defect level and impurity level are generated in the lattice defect, and a current is leaked in a reverse direction through these levels, and there is no method but improving the crystal itself for improving the reverse withstand voltage property.

An object of the present invention is to provide a semiconductor diode capable of greatly improving a reverse withstand voltage property without inviting an increase of on-resistance.

According to a first aspect of the present invention, there is provided a semiconductor diode having a mesa structure portion formed by etching and removing a part of a semiconductor lamination portion in which an n-type semiconductor layer and a p-type semiconductor layer are laminated on a substrate to thereby form a pn-junction, so as to extend from a main surface of the p-type semiconductor layer to a part of the n-type semiconductor layer, comprising:

a protective insulating film formed by coating a main surface of the mesa structure portion, a side face of the mesa structure portion in which an interface of the pn-junction is exposed, and an etched and exposed surface of the n-type semiconductor layer; and

an anode electrode formed in ohmic-contact with the p-type semiconductor layer exposed from an opening formed on a part of the main surface of the mesa structure portion of the protective insulating film, extending from the main surface, through the side face of the mesa structure portion, to the surface of the n-type semiconductor layer.

According to a second aspect of the present invention, there is provided the semiconductor diode of the first aspect, wherein a semiconductor constituting the semiconductor lamination portion is a nitride semiconductor.

According to a third aspect of the present invention, there is provided the semiconductor diode of the second aspect, wherein the nitride semiconductor is gallium nitride.

According to a fourth aspect of the present invention, there is provided the semiconductor diode of the second or third aspect, wherein the substrate is an n-type nitride gallium substrate.

According to a fifth aspect of the present invention, there is provided the semiconductor diode of the fourth aspect, wherein a cathode electrode is provided on the n-type gallium nitride substrate.

According to a sixth aspect of the present invention, there is provided the semiconductor diode of the first aspect, wherein the protective insulating film is a SiO₂ film.

According to a seventh aspect of the present invention, there is provided the semiconductor diode of the second aspect, wherein a dopant of the p-type semiconductor layer is magnesium.

According to an eighth aspect of the present invention, there is provided the semiconductor diode of the second aspect, wherein a dopant of the n-type semiconductor layer is silicon.

According to the present invention, the semiconductor diode capable of greatly improving the reverse withstand voltage property without inviting the increase of the on-resistance, can be obtained.

### BRIEF DESCRIPTION OF THE DRAWINGS

FIG. 1 is a cross-sectional view schematically showing a structure of a semiconductor diode of comparative example 1 without a protective insulating film.

FIG. 2 is a cross-sectional view schematically showing a structure of a semiconductor diode of comparative example 2 with the protective insulating film.

FIG. 3 is a cross-sectional view schematically showing a structure of a semiconductor diode of comparative example 3 with the protective insulating film and field plates.

FIG. 4 is a cross-sectional view schematically showing the structure of a semiconductor diode according to an embodiment and an example of the present invention.

FIG. 5 is a graph showing a reverse withstand voltage property of the semiconductor diode of comparative example 1.

FIG. 6 is a graph showing the reverse withstand voltage property of the semiconductor diode of an example of the present invention.

FIG. 7 is a graph showing a comparison of the reverse withstand voltage properties between comparative examples 1 to 3, and the example of the present invention.

FIG. 8 is a graph showing a comparison of forward current/voltage properties between comparative examples 1 to 3, and the example of the present invention.

### DETAILED DESCRIPTION OF THE INVENTION

Embodiments of a semiconductor diode according to the present invention will be described hereafter. FIG. 4 is a cross-sectional view schematically showing a structure of a semiconductor diode according to an embodiment of the present invention.

As shown in FIG. 4, the semiconductor diode of this embodiment comprises a semiconductor lamination portion in which n-type GaN (gallium nitride) layers 5, 4, being n-type semiconductor layers, and p-type GaN layers 3, 2, being p-type semiconductor layers, are sequentially laminated on a substrate 6, and a pn-junction interface 9 is formed on the interface between the n-type GaN layer 4 and the p-type GaN layer 3. Further, the semiconductor diode of this embodiment has a mesa structure portion 10 extending from a main surface of the p-type GaN layer 2 to a part of the n-type GaN layer 4, with a part of the semiconductor lamination portion etched and removed. A protective insulating film (passivation film) 8 made of SiO₂, etc., for example, is formed on a main surface of the mesa structure portion 10 (main surface of the p-type GaN layer 2 in this embodiment) and a side face 10b of the mesa structure portion 10 with an exposed pn-junction interface 9, and an etched and exposed surface 4a of the n-type GaN layer 4, by being coated thereon. Thus, the surface of the semiconductor layer including the mesa structure portion 10 is protected. Further, an anode electrode 1 is formed on the protective insulating film 8 so as to be extended to the main surface 10a and the side face 10b of the mesa structure portion 10 and the surface 4a of the n-type GaN layer 4. Namely, the anode electrode 1 has an ohmic junction portion 1a which is brought into ohmic-contact with the p-type GaN layer 2 exposed from an opening 8a of the protective insulating film 8; field plate portions 1b formed on the protective insulating film 8 positioned in an upper part of the p-type GaN layer 2 outside of the opening 8a; and extending structure portions (or pn-junction surface coating portions) 1c further extending from the field plate portions 1b up to the side face 10b of the mesa structure portion 10 and the surface 4a of the n-type GaN layer 4. Further, a cathode electrode 7 is formed on a rear surface of the substrate 6.

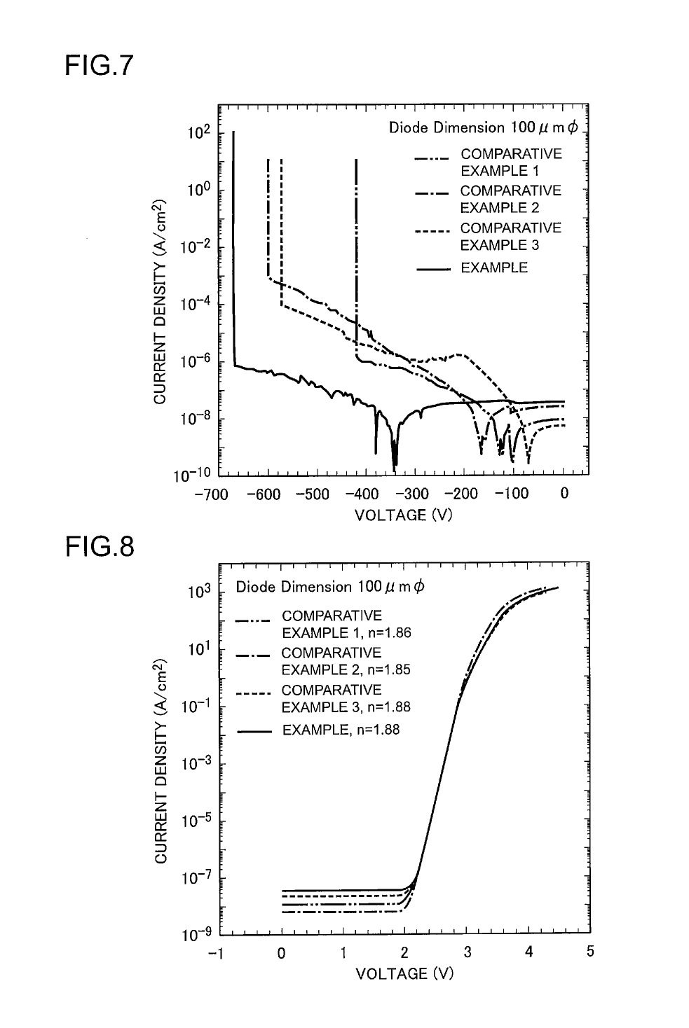

Although the semiconductor diode of this embodiment has a non-planar type (recess type) pn-junction structure not having a p-type embedding structure, it is found that a reverse leak current can be reduced and the reverse withstand voltage can be improved without increasing the on-resistance of the pn-junction diode, by providing the anode electrode 1 on the side face 10b of the mesa structure portion 10 with the protective insulating film 8 interposed between teh anode electrode 1 and the side face 10b, so as to cover the pn-junction surface layer, with the pn-junction interface 9 exposed (for example, see FIG. 7 and FIG. 8).

In the pn-junction diode not having the planar structure, it is probable that the electric field concentration occurs not only on the crystal surface layer but also on an entire body of the pn-junction. However, when a dramatic improving effect of the reverse leak current and the reverse withstand voltage in the pn-junction diode of this embodiment not having the planar structure, is taken into consideration, not only a generally supposed electric field concentration to the pn-junction interface is considered to be a factor of deteriorating the device characteristic, namely deteriorating the reverse leak current and the reverse withstand voltage.

Conventionally, as other factor of deteriorating the aforementioned device characteristic, trap-level caused by a lattice defect such as a dislocation in a crystal can be considered. This is not solved by a structure or a shape of an electrode. However, in the semiconductor diode of this embodiment, a tremendous improvement effect is recognized by the structure or the shape of the anode electrode. Although a reason thereof is not certain, the following possibility can be considered. Conventionally, there is a possibility that a certain kind of electronic level exists, due to surface physical properties such as a surface damage layer during processing, and an unpaired electron which is related to a crystal orientation of a processing surface. However, these physical properties are not problems conventionally. Also, there is a possibility of generating deterioration of the characteristics, such as flowing of a leak current through these portions. It is considered that an electric potential is changed by covering the problematic portions regarding the aforementioned surface physical properties, and these portions are not the flowing paths of the leak current any more.

Thus, the cause for deteriorating the device characteristic and the reason for the tremendous improvement effect thereof are not clarified. However, by employing the anode electrode structure of the present invention as shown in the aforementioned embodiment, it is found that a withstand voltage can be improved while maintaining a low on-resistance, without being restricted by a trade-off relation between the on-resistance and the withstand voltage, which is a problem conventionally. Namely, in this embodiment, the semiconductor diode with high withstand voltage and low-current application loss, can be provided.

As the aforementioned substrate 6, an n-type GaN substrate (GaN freestanding substrate) with low dislocation density is preferably used. Dislocation, being one of the crystal defects involves a problem of increasing the leak current and deteriorating the reverse withstand voltage property. In a case of using a substrate having a thermal expansion coefficient and a lattice constant different from those of a material of an epitaxial layer that constitutes the semiconductor diode, high-density dislocation is generated between the epitaxial layer and the substrate. Therefore, the same GaN substrate as the GaN epitaxial layer is preferably used.

Further, the cathode electrode 7 is preferably provided on a rear surface of the substrate 6, which is the opposite side to the anode electrode 1. In a case of a device for flowing a large current, a size of the cathode electrode is required to be increased. Therefore, when the cathode electrode is also provided on an upper surface side of the device similarly to the anode electrode, a device area needs to be taken wider, thus reducing the number of acquirable devices per wafer, and increasing a cost.

Note that in the aforementioned embodiment, GaN (gallium nitride) is used as a semiconductor that constitutes the semiconductor lamination portion. However, a similar effect can be expected even in a case of using a nitride semiconductor excluding GaN, namely using a material such as AlGaN, InGaN, InAlN, BGaN, etc., or using a material such as SiC.

### EXAMPLES

Examples of the present invention will be described next.

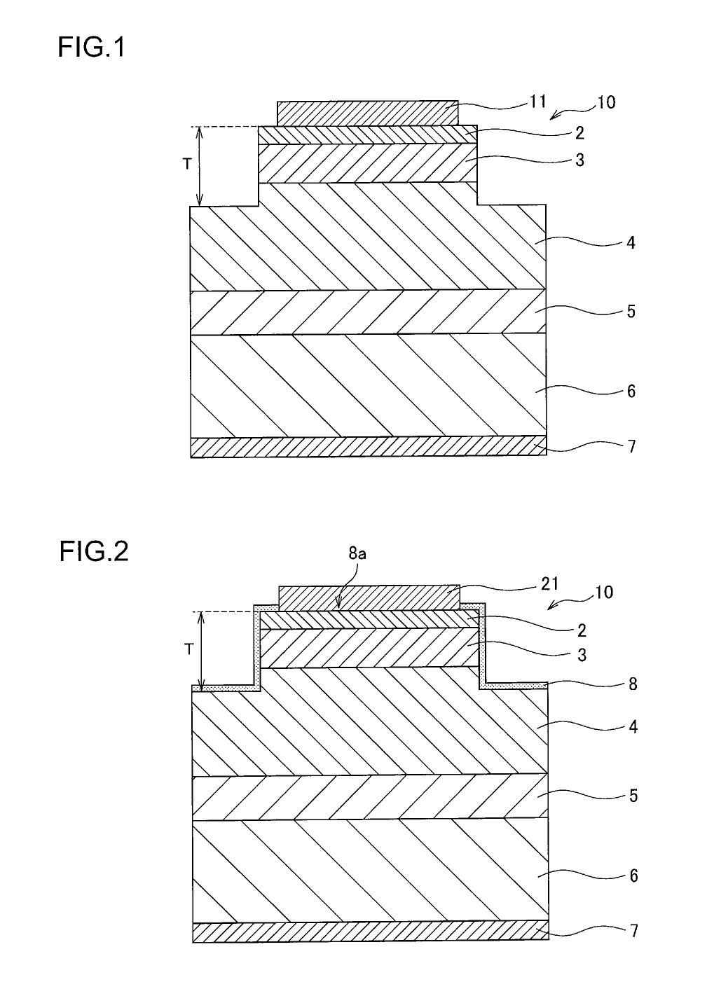

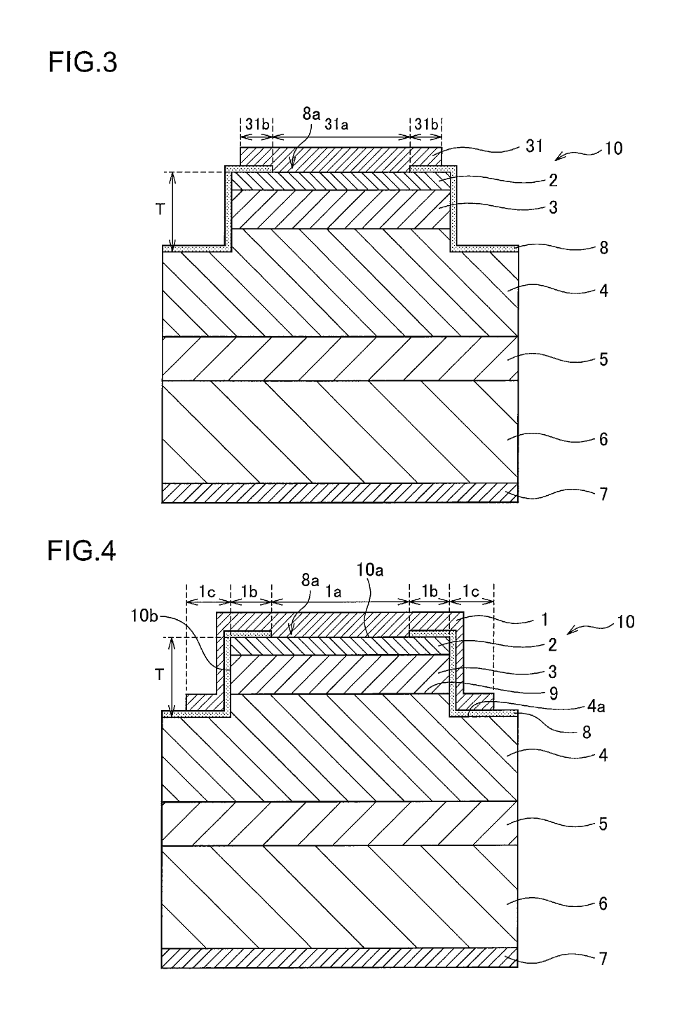

The semiconductor diode according to an example of the present invention has a structure similar to the structure of the semiconductor diode according to the aforementioned embodiment shown in FIG. 4. Therefore, the semiconductor diode according to this example will be described using FIG. 4. Further, semiconductor diodes of comparative examples 1, 2, 3 to be compared and evaluated with this example, are shown in FIG. 1, FIG. 2, and FIG. 3 respectively.

### Example

A method for manufacturing the semiconductor diode of the example of the present invention will be described.

First, as a substrate, a low dislocation-density (about 10⁶/cm²) n-type GaN substrate (carrier concentration: 1×10¹⁸/cm³, thickness: 400 μm) 6 was prepared using a Void-Assisted Separation, (VAS) method. Then, Si-doped n-type GaN layers 5, 4 and Mg-doped p-type GaN layers 3, 2 were laminated on the n-type GaN substrate 6 using a Metal Organic Chemical Vapor Deposition Epitaxy (MOVPE) method, to thereby form a semiconductor lamination portion. The structure of each layer of the semiconductor lamination portion is as follows. Namely, the n-type GaN layer 5 has a Si concentration of 2×10¹⁸/cm³, a thickness of 2 μm, and the n-type GaN layer 4 has a Si concentration of 2×10¹⁶/cm³ and a thickness of 10 μm, and the p-type GaN layer has a Mg concentration of 2×10¹⁹/cm³ and a thickness of 500 nm, and the p-type GaN layer 2 has a Mg concentration of 2×10²⁰/cm³ and a thickness of 20 nm. Note that substantially a similar result was confirmed in the p-type GaN layer 3 with a Mg concentration in range of 5×10¹⁷/cm³ to 2×10¹⁹/cm³.

Next, a part of the semiconductor lamination portion was removed by etching, to thereby form a mesa structure portion 10. ICP-RIE apparatus (inductive coupling plasma-reactive ion etching apparatus) was used for etching, to thereby form the mesa structure portion 10 extending from a main surface of the p-type GaN layer 2 to a part of the n-type GaN layer 4 (for example, T=800 nm, or T=550 nm).

Subsequently, the main surface 10a and the side face 10b of the mesa structure portion 10, and the surface 4a of the etched and exposed n-type GaN layer 4, were formed by coating them with a SiO₂ film (described as SiO₂ film 8 hereafter), being the protective insulating film 8. The SiO₂ film 8 was formed by coating it with SOG (Spin On Glass) and thereafter applying heat treatment thereto. Note that the SiO₂ film 8 may also be formed by sputtering. A film thickness of the SiO₂ film 8 is preferably set to 70 nm or more, and was set to 300 nm. Not only SiO₂ but also SiN and SiON, etc., may be used for the material of the protective insulating film, and in a case of the SiN with a thickness of 200 nm or more as well, a result similar to the result of the SiO₂ can be obtained. Further, the opening 8a was formed by etching in a central portion of the SiO₂ film 8 on the main surface 10a of the mesa structure portion 10.

Subsequently, as the ohmic electrode, the anode electrode 1 was formed on the upper surface side of the n-type GaN substrate 6 including the mesa structure portion 10, and the cathode electrode 7 was formed on the rear surface thereof by electron beam vapor-deposition respectively. The anode electrode 1 was formed by laminating thereon a Pd layer (with a thickness of 20 nm), a Ti layer (with a thickness of 33 nm), a Pt layer (with a thickness of 33 nm), and an Al layer (with a thickness of 200 nm) in this order. The cathode electrode 7 was formed by laminating thereon a Ti layer (with a thickness of 50 nm) and an Al layer (with a thickness of 200 nm) in this order. Further, heat treatment of 1 minute was applied to the cathode electrode 7 in a nitrogen atmosphere at 550° C.

Thereafter, the substrate that has undergone the aforementioned treatment was divided into each device by dicing, to thereby obtain the semiconductor diodes of the example. Semiconductor diodes have a cylindrical shape with diameters of 60 μm, 100 μm, 200 μm, 400 μm, and 800 μm.

### Comparative Examples 1 to 3

In the semiconductor diodes of comparative examples 1, 2, 3 shown in FIG. 1, FIG. 2, and FIG. 3 respectively, the structure of the anode electrode and whether the SiO₂ film 8 exists or not are different from the semiconductor diode of the example. However, the p-type GaN layers 2, 3, the n-type GaN layers 4, 5, the n-type GaN substrate 6, the cathode electrode 7, and the mesa structure portion 10 have the same structure and the same constitution. Further, anode electrodes 11, 21, of comparative examples 1, 2, 3 have the same four-layer structure as the structure of the anode electrode 1 of the aforementioned example, and the SiO₂ film 8, being the protective insulating film, also has the same structure.

The semiconductor diode of comparative example 1 shown in FIG. 1 has a structure without the protective insulating film (passivation film), with the anode electrode 11 formed in the central portion of the main surface of the p-type GaN layer 2. The semiconductor diode of comparative example 2 shown in FIG. 2 has the SiO₂ film 8, with the anode electrode 21 formed on the p-type GaN layer 2 exposed from the opening 8a of the SiO₂ film 8. The semiconductor diode of comparative example 3 shown in FIG. 3 has a structure that the anode electrode 31 has the ohmic junction portion 31a of the opening 8a, and the field plate portions 31b on the SiO₂ film 8 outside of the ohmic junction portion 31a.

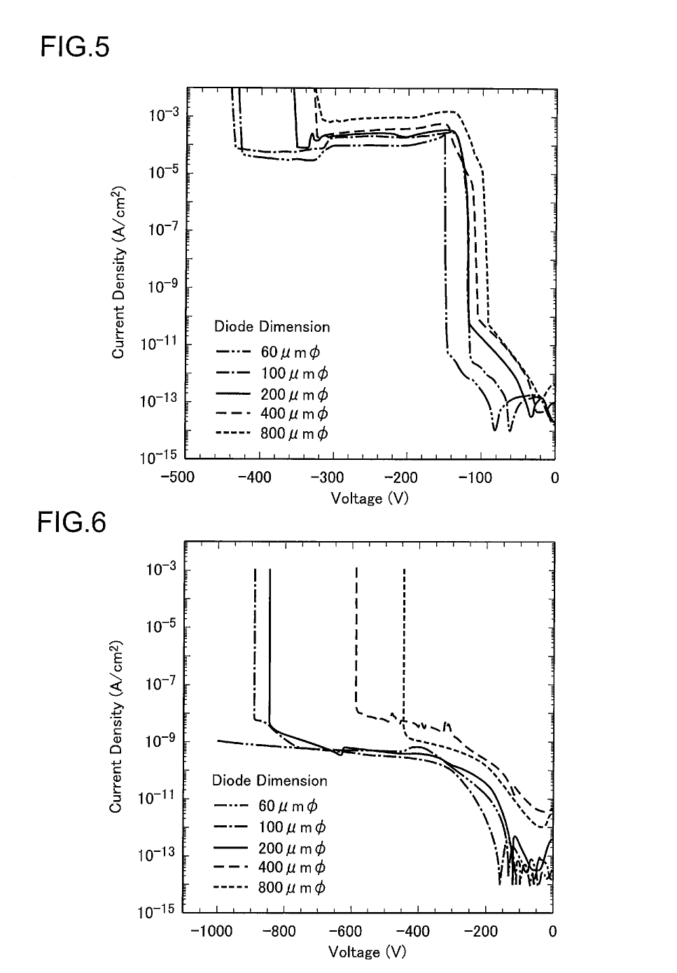

FIG. 5 shows the reverse current/voltage properties of the semiconductor diode (having a size of 60 μm to 800 μm) of comparative example 1, and FIG. 6 shows the reverse current/voltage properties of the semiconductor diode of the example. Note that current/voltage (I-V) properties were measured at a room temperature by a Model 237 High-Voltage Source-Measure Unit by Keithley Instruments., Inc.

As shown in FIG. 5, in the semiconductor diode of comparative example 1, an absolute value of the breakdown voltage is 430V or less. Further, detailed observation reveals that the leak current is suddenly increased to 0.1 mA/cm² from 10 pA/cm² in the vicinity of −100V, and therefore the reverse voltage of −100V or larger can't be added.

Meanwhile, as shown in FIG. 6, in the semiconductor diode of the example, the absolute value of the breakdown voltage exceeds 1 kV in a case of the diode with a diameter of 60 μm. Further, in this voltage as well, the leak current keeps a value of 1 nA/cm². Thus, the absolute value of the breakdown voltage is 800V or more in the diode with diameters of 100 μm and 200 μm which are larger than 60 μm. Further, in the diode with a diameter of 800 μm, which is easily affected by the crystal defects, the leak current at −400V is 10 nA/cm² or less and is extremely small, thus showing a clear difference from a conventional diode of comparative example 1.

FIG. 7 shows a result of comparing the reverse current/voltage properties in the semiconductor diodes (with a size of 100 μm respectively) between comparative examples 1 to 3 and the example. FIG. 8 shows a result of comparing the forward current/voltage properties in the semiconductor diodes (with a size of 100 μm respectively) between comparative examples 1 to 3 and the example. Note that in FIG. 8, n indicates an Ideality Factor.

As is clarified from FIG. 7, only a low leak current of 1 μA/cm² or less flows even at a high voltage of −650V in the structure of the example only, wherein the absolute value of the breakdown voltage exceeds 650V in this case. Meanwhile, as is clarified from FIG. 8, completely the same forward properties are observed in the comparative examples 1 to 3, and the example. Namely, this result shows that high withstand voltage can be realized without sacrificing the forward properties.

What is claimed is:

1. A semiconductor diode having a mesa structure portion formed by etching and removing a part of a semiconductor lamination portion in which an n-type semiconductor layer and a p-type semiconductor layer are laminated on a substrate to thereby form a pn-junction, so as to extend from a main surface of the p-type semiconductor layer to a part of the n-type semiconductor layer, comprising:
a protective insulating film formed by coating a main surface of the mesa structure portion, a side face of the mesa structure portion in which an interface of the pn-junction is exposed, and an etched and exposed surface of the n-type semiconductor layer; and
an anode electrode formed in ohmic-contact with the p-type semiconductor layer exposed from an opening formed on a part of the main surface of the mesa structure portion of the protective insulating film, extending from the main surface, through the side face of the mesa structure portion, to the surface of the n-type semiconductor layer.

2. The semiconductor diode according to claim 1, wherein a semiconductor constituting the semiconductor lamination portion is a nitride semiconductor.

3. The semiconductor diode according to claim 2, wherein the nitride semiconductor is gallium nitride.

4. The semiconductor diode according to claim 2 or 3, wherein the substrate is an n-type gallium nitride substrate.

5. The semiconductor diode according to claim 4, wherein a cathode electrode is provided on the n-type gallium nitride substrate.

7. The semiconductor diode according to claim 2, wherein a dopant of the p-type semiconductor layer is magnesium.

8. The semiconductor diode according to claim 2, wherein a dopant of the n-type semiconductor layer is silicon.
